(19) United States
(12) Patent Application Publication
(10) Pub. No.: US 2026/0341655 A1
(43) Pub. Date: Oct. 29, 2026

(54) Counter-Impedance Matching Network For Process Chambers With Remote Plasma Sources

(71) Applicant: Applied Materials, Inc., Santa Clara, CA (US)

(72) Inventors: Punyabrahma PANDA, Bengaluru (IN); Ganapathy SARAVANAVEL, Bengaluru (IN); Virendra RATHOD, Bengaluru (IN); Syam Sundeep BOOSA, Bengaluru (IN); Saravanan CHANDRABALU, Bengaluru (IN); Suresh Chand SETH, Bengaluru (IN)

(21) Appl. No.: 19/193,068

(22) Filed: Apr. 29, 2025

(51) Int. Cl. H01J 37/32

(52) U.S. Cl. CPC H01J 37/32935; H01J 37/32183; H01J 37/32357; H01J 2237/24592; H01J 2237/3321

(57) ABSTRACT

Methods and apparatus for calibrating RF generators on chemical vapor deposition chambers that use a multi-function adapter. In some embodiments, a counter-impedance matching network is used that is positionable directly across a top of a process volume of the process chamber. The counter-impedance matching network has a vertical input on a bottom of a first end of the counter-impedance matching network that is configured to connect with a lid connection point of a vertical electrode electrically connected to a multi-frequency adapter (MFA). The counter-impedance matching network has a second end distal to the first end that has a downward protrusion that is configured to be insertable into an opening positioned at a front of the process chamber. The counter-impedance matching network has an impedance with a reactive component that is equal and opposite to a reactive component of the impedance of the MFA to allow accurate calibration of the RF generator.

### FIELD

Embodiments of the present principles generally relate to semiconductor processing of semiconductor substrates.

### BACKGROUND

Some semiconductor chambers utilize RF generators that are positioned below the chambers. The RF generators are connected to the lid of the chamber via an electrode to provide power to the lid for generation of capacitively coupled plasma in the process volume of the chamber. A multi-frequency adapter (MFA) may be used to connect the RF generator (high frequency generator) to the electrode when more than one RF generator (low frequency generator) is connected to the process chamber. When calibrating the RF generator, the impedance of the MFA must be counteracted to provide an accurate calibration of the RF generator. A counter-impedance matching network is installed to offset the reactive component of the impedance of the MFA to increase calibration accuracy. However, the inventors have observed that the lid cover and remote plasma source (RPS) must be removed to provide a connection from the counter-impedance matching network to the MFA. Removal of the lid cover, and especially removal of the RPS, takes a substantial amount of time and specialized training. Reinstallation of the lid cover and RPS takes additional time as realignment and calibrations must be performed on the RPS. The requirement to remove the lid cover and RPS leads to substantial down time for the process chamber which leads to infrequent calibrations of the RF generator and less than optimal performance of the process chamber over time.

Accordingly, the inventors have provided improved apparatus and methods for calibrating the RF generator without requiring removal of the lid cover or RPS, substantially simplifying the RF generator calibration process and reducing the process chamber downtime.

### SUMMARY

Methods and apparatus for calibrating RF generators for process chambers are provided herein.

In some embodiments, a method of calibrating an RF generator for a process chamber may comprise exposing a lid connection point of a vertical electrode electrically connected to a multi-frequency adapter (MFA) by opening a lid of the process chamber to an opening angle of approximately 90 degrees or more exposing a process volume where the MFA is electrically connected to the RF generator and positioning a counter-impedance matching network directly across a top of the process volume of the process chamber and electrically connecting a vertical input on a bottom on a first end of the counter-impedance matching network to the lid connection point of the vertical electrode where the counter-impedance matching network has a first impedance with a reactive component equal and opposite to a reactive component of a second impedance of the MFA and the counter-impedance matching network is connectable to a dummy load for performing a calibration of the RF generator.

In some embodiments, the method may further include an RF generator that is mounted below the process volume of the process chamber, a dummy load that is a 50-ohm load, an RF generator that is a high frequency RF generator, positioning the counter-impedance matching network directly across the top of the process volume of the process chamber that includes inserting a downward protrusion positioned on a second end of the counter-impedance matching network distal to the first end of the counter-impedance matching network into an opening positioned at a front of the process chamber, an MFA that is configured to accept a high frequency input from the RF generator and a low frequency input from another RF generator, a process chamber that is a chemical vapor deposition (CVD) chamber, a process chamber that has a remote plasma source (RPS) mounted to the lid which remains in-situ while the RF generator is calibrated, performing a calibration of the RF generator that includes accounting for impedance effects of the MFA on power transmitted into the process chamber by the RF generator, performing a calibration of the RF generator that includes adjusting set points for a process recipe performed with the process chamber, a counter-impedance matching network that has a horizontal protrusion that allows the first end of the counter-impedance matching network to be positioned under the lid when opened to connect the vertical input to the lid connection point of the vertical electrode, performing a calibration of the RF generator that is performed during preventive maintenance, performing a calibration of the RF generator that is used to detect damage to the MFA, and/or performing a calibration of the RF generator that is performed without removing a lid cover of the process chamber.

In some embodiments, a method of calibrating an RF generator for a process chamber may comprise exposing a lid connection point of a vertical electrode electrically connected to a multi-frequency adapter (MFA) by opening a lid of a chemical vapor deposition (CVD) process chamber to an opening angle of approximately 90 degrees or more exposing a process volume where the MFA is electrically connected to the RF generator, the RF generator is mounted below the process volume of the CVD process chamber, and the RF generator is a high frequency RF generator and positioning a counter-impedance matching network directly across a top of the process volume of the CVD process chamber and electrically connecting a vertical input on a bottom on a first end of the counter-impedance matching network to the lid connection point of the vertical electrode and inserting a downward protrusion positioned on a second end of the counter-impedance matching network distal to the first end of the counter-impedance matching network into an opening positioned at a front of the CVD process chamber where the counter-impedance matching network has a first impedance with a reactive component equal and opposite to a reactive component of a second impedance, the counter-impedance matching network is connectable to a 50-ohm dummy load for performing a calibration of the RF generator, and the calibration is performed without removing a lid cover of the CVD process chamber or a remote plasma source (RPS) of the CVD process chamber.

In some embodiments, the method may further include an MFA that is configured to accept a high frequency input from the RF generator and a low frequency input from another RF generator, performing a calibration of the RF generator that includes accounting for impedance effects of the MFA on power transmitted into the process chamber by the RF generator, performing a calibration of the RF generator that includes adjusting set points for a process recipe performed with the process chamber, and/or performing a calibration of the RF generator that is used to detect damage to the MFA.

In some embodiments, an apparatus for calibrating an RF generator of a process chamber may comprise a counter-impedance matching network that is configured to be positionable directly across a top of a process volume of the process chamber when a lid of the process volume is opened to an angle of approximately 90 degrees or more to expose the process volume where the counter-impedance matching network has a vertical input on a bottom of a first end of the counter-impedance matching network that is configured to connect with a lid connection point of a vertical electrode electrically connected to a multi-frequency adapter (MFA), the counter-impedance matching network has a second end distal to the first end with a downward protrusion that is configured to be insertable into an opening positioned at a front of the process chamber, and the counter-impedance matching network has a first impedance with a reactive component equal and opposite to a reactive component of a second impedance of the MFA.

Other and further embodiments are disclosed below.

### BRIEF DESCRIPTION OF THE DRAWINGS

Embodiments of the present principles, briefly summarized above and discussed in greater detail below, can be understood by reference to the illustrative embodiments of the principles depicted in the appended drawings. However, the appended drawings illustrate only typical embodiments of the principles and are thus not to be considered limiting of scope, for the principles may admit to other equally effective embodiments.

FIG. 1 depicts a cross-sectional view of a process chamber in accordance with some embodiments of the present principles.

FIG. 2 depicts a cross-sectional view of a process chamber with a lid cover removed in accordance with some embodiments of the present principles.

FIG. 3 depicts a cross-sectional view of a process chamber with a counter-impedance matching network in place in accordance with some embodiments of the present principles.

FIG. 4 depicts an isometric view of a counter-impedance matching network in accordance with some embodiments of the present principles.

FIG. 5 depicts a side view and a front view of a counter-impedance matching network in accordance with some embodiments of the present principles.

FIG. 6 depicts a block diagram of a system for calibrating an RF generator in accordance with some embodiments of the present principles.

FIG. 7 is a method of calibrating an RF generator in accordance with some embodiments of the present principles.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

The methods and apparatus provide a convenient and cost-effective way to calibrate RF generators that use multi-frequency adapters (MFAs) to provide RF power to capacitively coupled plasma (CCP) process chambers. The smaller size and shape of the counter-impedance matching network of the present techniques allows the match to be attached to the RF electrode of the MFA without requiring removal of the lid cover or remote plasma source (RPS). The removal and reinstallation of the RPS requires skilled personnel and substantial time, increasing the downtime of the process chamber. The counter-impedance matching network of the present techniques utilizes state of the art capacitors and inductors to counter the reactive component of the impedance of the MFA to enhance calibration and serviceability of the process chamber during preventative maintenance. The present techniques allow for easier access to the MFA, promoting frequent calibration checks which aid in maintaining optimal performance of the RF generator and process chamber.

In some semiconductor process chambers, an RF generator is connected to the lid of the process chamber using an MFA which may also be referred to as a ‘fixed match’ with a center impedance of, for example but not limited to, 7−j14. The MFA allows a process chamber to have incoming RF power from two different RF generators such as a low frequency RF generator and a high frequency RF generator. To calibrate an RF generator connected to the process chamber with a fixed match or an MFA, a counter-impedance matching network is added to compensate for the reactive component of the impedance of the fixed match (e.g., “7−j14” is countered with “7+j14” in the example). As a fixed match's impedance may change around the center impedance with time, the incoming RF power from the RF generator needs to be calibrated for optimal chamber performance.

Traditionally, the chamber lid cover must be removed to allow the counter-impedance matching network to be installed over the top of the lid. The counter-impedance matching network is then connected to a 50 Ω dummy load via a coaxial cable. The calibration may be performed during preventive maintenance and during the installation phase of the process chamber. However, with the traditional design of the counter-impedance matching network, the calibration cannot be performed without removing the chamber lid cover. For chambers with an RPS mounted to the lid cover, the RPS must also be removed which is very difficult and time consuming. Even more problematic is the reinstallation of the RPS which requires skilled personnel to align and calibrate. The counter-impedance matching network of the present techniques solves the issues by providing a higher performing and better designed counter-impedance matching network that can be installed without removing the lid cover or RPS, saving both time and reducing costs during calibration of the RF generator. The enhanced counter-impedance matching network has state of the art impedance components which are lighter and substantially more compact (counter-impedance matching network weighs less than 500 grams). The counter-impedance matching network can be easily installed and removed, allowing for more frequent calibration checks which aid in prolonging the life of the RF generator and process chamber. In some embodiments, the present techniques can be used to easily and quickly calibrate high frequency RF generators on CVD process chambers and the like that have an MFA.

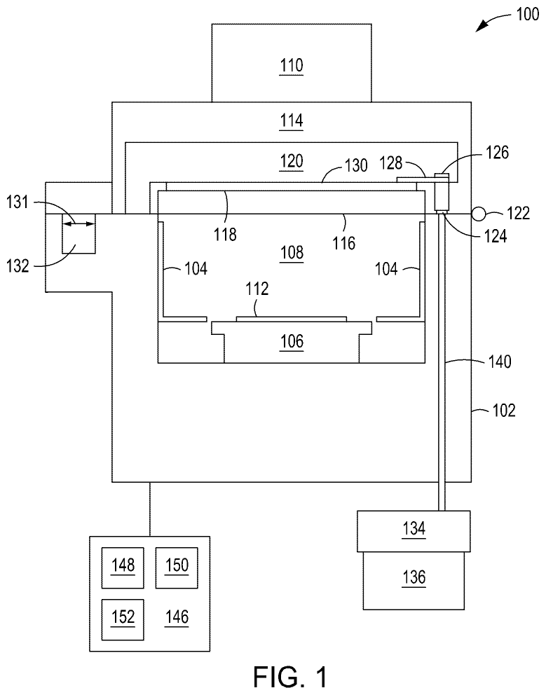

FIG. 1 depicts a process chamber 100 that may be utilized with a counter-impedance matching network of the present techniques. The process chamber 100 may be a CVD process chamber without or with an RPS (shown). The process chamber 100 includes a chamber body 102 that includes a process volume 108 where capacitively coupled plasma is generated to process a wafer 112. The wafer 112 is on a substrate support 106. The process volume 108 may be at least partially shielded with a process shield 104. At the top of the process volume 108 is a lid 116 and a gas manifold 118 from which a process gas or other gases are injected into the process volume 108. A clamp 120 is in contact with an upper surface 130 of the gas manifold 118 to secure the gas manifold 118 to the lid 116. The lid cover 114 provides protection over the lid 116 and associated hardware such as the clamp 120 and the gas manifold 118. A lid hinge 122 allows the lid 116, the lid cover 114, the RPS 110, and associated hardware to pivot rearward to access the process volume 108 of the process chamber 100.

The process chamber 100 may have an opening 132 with a given diameter 131 that is accessible when the process chamber 100 is opened. In the example process chamber, an RPS 110 is mounted to the top of the lid cover 114. The gas manifold 118 and/or the lid 116 may be in electrical contact with an RF power strap 128 that connects to an upper RF power connection point 126. The upper RF power connection point 126 is electrically connected to a lower RF power connection point 124. The lower RF power connection point 124 is then connected to an RF electrode 140 which is electrically connected to an MFA 134. The MFA 134 is electrically connected to at least one RF power generator such as the RF power generator 136. The RF power generator 136 may be a high frequency power generator (e.g., 13.56 MHz, etc.) that is operated in conjunction with a low frequency power generator (e.g., 350 kHz, etc.) (not shown) via the MFA 134.

A controller 146 controls the operation of the process chamber 100 using direct control or alternatively, by controlling the computers (or controllers) associated with the process chamber 100. In operation, the controller 146 enables data collection and feedback to optimize performance of the process chamber 100. The controller 146 generally includes a Central Processing Unit (CPU) 148, a memory 150, and a support circuit 152. The CPU 148 may be any form of a general-purpose computer processor that can be used in an industrial setting. The support circuit 152 is conventionally coupled to the CPU 148 and may comprise a cache, clock circuits, input/output subsystems, power supplies, and the like. Software routines and/or power calibrations for recipes or process profiles and the like, such as used in the methods and/or apparatus as described herein may be stored in the memory 150 and, when executed by the CPU 148, transform the CPU 148 into a specific purpose computer (controller 146). The software routines may also be stored and/or executed by a second controller (not shown) that is located remotely from the process chamber 100.

The memory 150 is in the form of computer-readable storage media that contains instructions, when executed by the CPU 148, to facilitate the operation of the semiconductor processes and equipment. The instructions in the memory 150 are in the form of a program product such as a program that implements the apparatus of the present principles. The program code may conform to any one of a number of different programming languages. In one example, the disclosure may be implemented as a program product stored on a computer-readable storage media for use with a computer system. The program(s) of the program product may be used to define functions of the aspects of the present techniques disclosed herein. Illustrative computer-readable storage media include, but are not limited to: non-writable storage media (e.g., read-only memory devices within a computer such as CD-ROM disks readable by a CD-ROM drive, flash memory, ROM chips, or any type of solid-state non-volatile semiconductor memory) on which information is permanently stored; and writable storage media (e.g., floppy disks within a diskette drive or hard-disk drive or any type of solid-state random access semiconductor memory) on which alterable information is stored. Such computer-readable storage media, when carrying computer-readable instructions that direct the functions of process chamber 100 and/or plasma exciter apparatus as described herein, are aspects of the present principles.

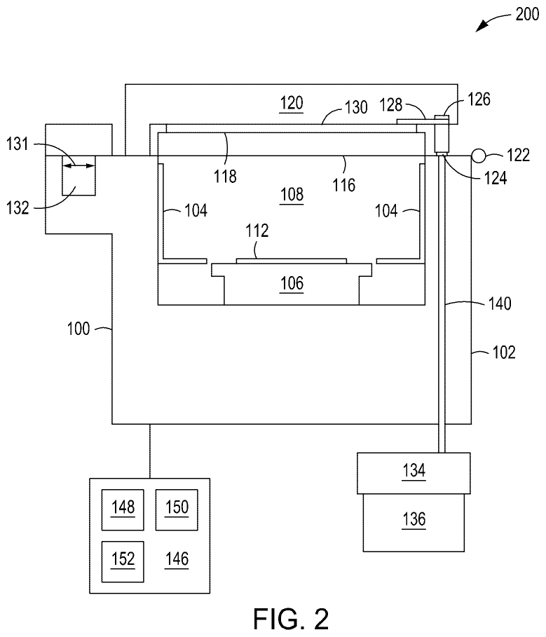

With traditional counter-impedance matching networks, to access the upper RF power connection point 126 to calibrate the RF power generator 136, the RPS 110 must be removed and then the lid cover 114 must be removed as depicted in a view 200 of FIG. 2. The removal of the lid cover 114 exposes the upper RF power connection point 126. However, the removal of the lid cover 114 and the RPS 110 takes the process chamber 100 out of the production line for a substantial amount of time. Especially in cases where the RPS 110 is removed, the process chamber 100 may be down for days due to the required use of skilled personnel to remove, reinstall, align, and then calibrate the RPS 110. The chamber downtime leads to lower yields and higher costs. The lengthy time for calibration access often delays calibration of the RF power generator 136 until deemed absolutely necessary. However, if the RF power generator 136 is out of specification during substrate processing, substandard processing may occur producing substrates with depositions or etchings that are out of acceptable tolerances, reducing yields, and may also lead to damage to the RF power generator 136.

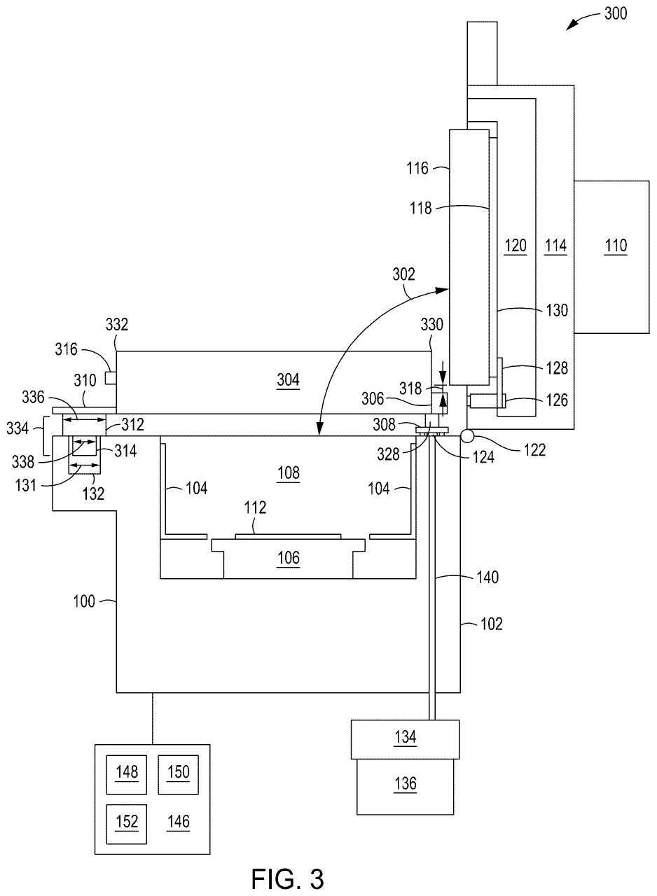

The inventors have found that by utilizing a counter-impedance matching network 304 that can be attached to the RF power generator 136 at the lower RF power connection point 124, the lid cover 114 and the RPS 110 do not need to be removed to calibrate the RF power generator 136 as depicted in a view 300 of FIG. 3. Access to the lower RF power connection point 124 can be achieved by opening the lid 116 in conjunction with the lid cover 114 and the RPS 110, leaving the lid cover 114 and the RPS 110 in-situ during calibration of the RF power generator 136. The lid 116 is opened to an angle 302 of approximately 90 degrees or more to expose the lower RF power connection point 124. The lower RF power connection point 124 was not able to be used with traditional counter-impedance matching networks due to the size and configuration of the traditional counter-impedance matching networks. A first RF connection 328 connects to the lower RF power connection point 124 and is mounted using a flange 308. The mounting of the flange (e.g., with bolts, screws, pins, etc.) provides stability for the counter-impedance matching network 304 and ensures that the electrical connection to the RF power generator 136 is not interrupted accidentally during calibration procedures.

The first RF connection 328 is generally a coaxial-type input with a center hot and grounded outer shell. The housing of the counter-impedance matching network 304 has a protrusion 306 on a first end 330 (the first RF connection end of the counter-impedance matching network 304) to allow connection of the counter-impedance matching network 304 to the lower RF power connection point 124 without interfering with the lid 116 by a given distance 318. The housing of the counter-impedance matching network 304 has a second end 332 with a second RF connection 316 which is distal to the first end 330 and has a flat horizontal extension 310 that extends outward with a downward protrusion 334. The downward protrusion 334 extends into the opening 132 of the process chamber 100 to facilitate in stabilizing the counter-impedance matching network 304 when calibrating the RF power generator 136. In some embodiments, the downward protrusion 334 may comprise a first portion 312 with a first diameter 336 larger than the diameter 131 of the opening 132 and a second portion 314 with a second diameter 338 smaller than the first diameter 336 and the diameter 131 of the opening 132. The second end 332 may also have a second RF connection 316 for connecting to a dummy load and/or test equipment and the like.

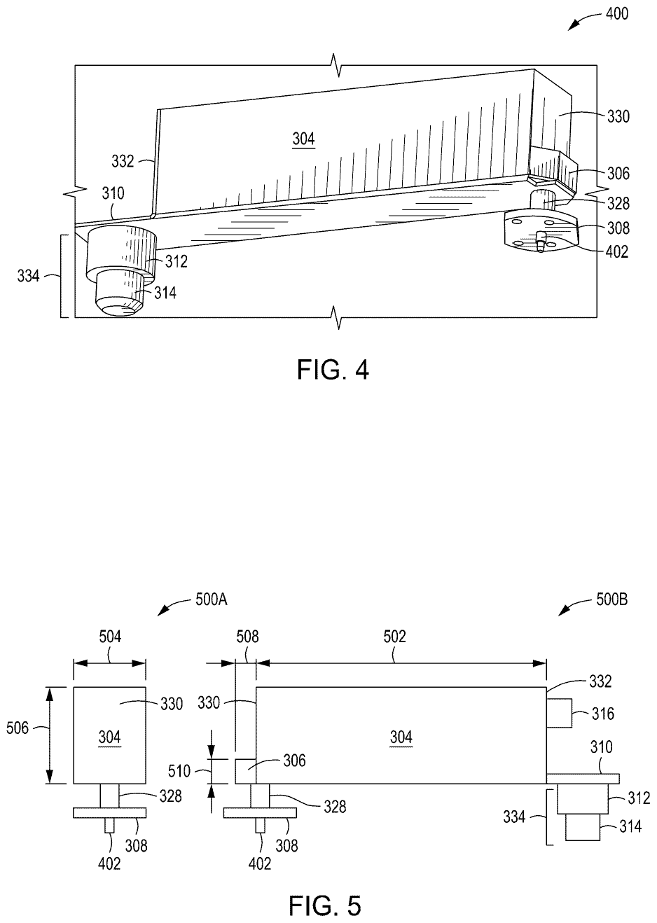

FIG. 4 depicts the counter-impedance matching network 304 in an isometric view 400. The first RF connection 328 has a coaxial-type connector 402 that interfaces with the lower RF power connection point 124 to connect to the RF electrode 140 connected to the MFA 134 and the RF power generator 136. FIG. 5 depicts a front-end view 500A and a side view 500B of the counter-impedance matching network 304. In some embodiments, the housing of the counter-impedance matching network 304 may have a length 502 of approximately 10 inches to approximately 15 inches. In some embodiments, the length 502 may be approximately 13 inches. In some embodiments, the height 506 of the housing of the counter-impedance matching network 304 may be approximately 2.5 inches to approximately 5 inches. In some embodiments, the height 506 may be approximately 3.75 inches. In some embodiments, the width 504 of the housing of the counter-impedance matching network 304 may be from approximately 2 inches to approximately 3.5 inches. In some embodiments, the width 504 may be approximately 3 inches. In some embodiments, the protrusion 306 on the first end 330 of the housing of the counter-impedance matching network 304 may have an extension 508 of approximately 0.5 inches to approximately 1.5 inches. In some embodiments, the extension 508 may be approximately 0.75 inches. In some embodiments, a protrusion height 510 of the protrusion 306 may be approximately 1.0 to approximately 1.25 inches.

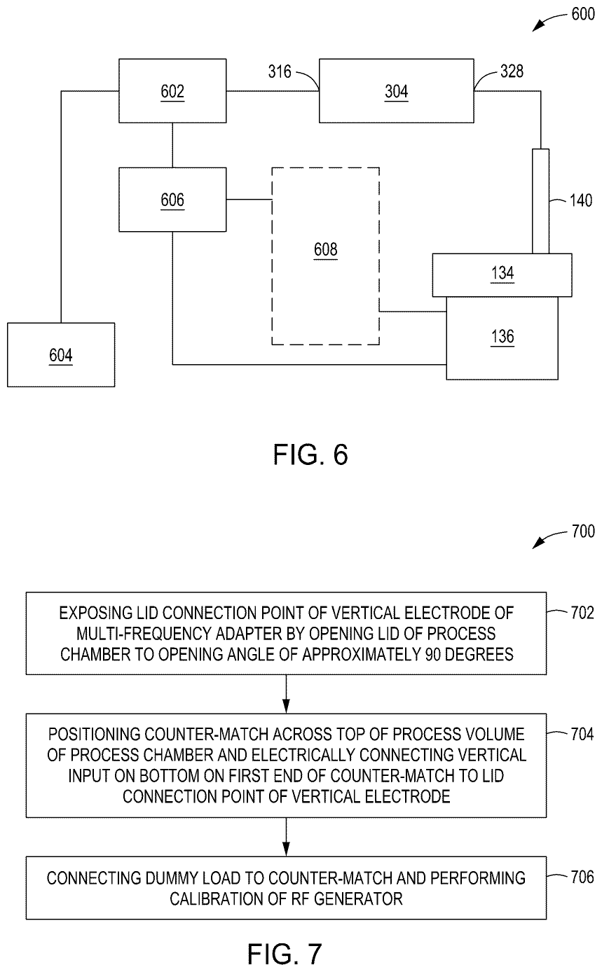

FIG. 6 depicts a calibration system 600 that incorporates the counter-impedance matching network 304 of the present techniques. The first RF connection 328 of the counter-impedance matching network 304 is connected to the RF electrode 140 which is connected to the MFA 134 and the RF power generator 136 which is under calibration. The second RF connection 316 is connected to a dummy load 604 (e.g., a 50-ohm dummy load, etc.) via a first test equipment 602 such as, for example, a power sensor and the like. The first test equipment 602 may be connected to a second test equipment 606 such as, for example, a power meter and the like. In some embodiments, a controller 608 may be connected to one or more of the test equipment and interface with the RF power generator 136 to indirectly calibrate the RF power generator via the controller 608. In some embodiments, the test equipment may be directly connected to the RF power generator 136 to directly calibrate the RF power generator 136.

In some embodiments, the RF power generator 136 is a 50-ohm load and the dummy load 604 will be a 50-ohm load. In some examples, the MFA 134 will have an impedance of, for example, 7−j14. The counter-impedance matching network 304 will then have an impedance of 7+j14 to counter the reactive impedance of the MFA 134 to allow for accurate calibration of the RF power generator 136 in-situ (no need to disconnect the RF power generator from the MFA, etc.). The counter-impedance matching network 304 of the present techniques may weigh less than 500 grams and is easily transported to the chamber and connected to the RF electrode 140 by merely lifting the lid of the chamber to an angle of approximately 90 degrees or more to install. The ease of installation without removing the lid cover or RPS allows for frequent and easy calibration of the RF power generator during every preventive maintenance without long down times, increasing yields while simultaneously optimizing the performance of the process chamber and prolonging the life of the chamber.

FIG. 7 is a method 700 of calibrating an RF generator for a process chamber. In some embodiments, the process chamber may have an RPS mounted to the lid or lid cover of the process chamber. In block 702, a lid connection point of a vertical RF electrode of a multi-frequency adapter is exposed by opening a lid of process chamber to an opening angle of approximately 90 degrees or more. In some process chambers, the RF generator is positioned below the process chamber and is electrically connected to the lid of the process chamber by the vertical RF electrode via the MFA. The MFA is used to connect a low frequency RF generator (e.g., 350 kHz, etc.) to the process chamber and a high frequency RF generator (e.g., 13.56 MHz, etc.) to the process chamber. In some examples, the MFA will act as a fixed match with an impedance, for example but not limited to, 7−j14. The chamber is a capacitively coupled plasma (CCP) chamber such as a CVD chamber where the lid acts as a conductive electrode to generate CCP in the process volume of the process chamber.

In block 704, a counter-impedance matching network (counter-match) is positioned across a top of a process volume of a process chamber and electrically connected to the vertical RF electrode on the bottom of the first end of the counter-impedance matching network to the lid connection point of the vertical RF electrode. In some embodiments, the counter-impedance matching network may have a downward protrusion positioned on a second end of the counter-impedance matching network distal to the first end of the counter-impedance matching network that is placed into the opening at the front of the process chamber to stabilize the counter-impedance matching network. The counter-impedance matching network is used to cancel out the reactive component of the MFA's impedance during calibration of the RF generator. In some embodiments, the counter-impedance matching network will have an impedance of 7+j14 when the MFA has an impedance of 7−j14. In some embodiments, the counter-impedance matching network may have a protrusion extending from the first end to allow connection (vertical input of the counter-impedance matching network) with the vertical RF electrode while providing clearance between the lid and the counter-impedance matching network.

In block 706, a dummy load is connected to the counter-impedance matching network and a calibration of the RF generator is performed. In some instances, the dummy load may be a 50-ohm dummy load to match the impedance of the RF generator (e.g., 50-ohm impedance). The calibration accounts for the impedance effects of the MFA on the power transmitted into the process chamber by the RF generator by using the counter-impedance matching network to offset the reactive component of the MFA. In some cases, the calibration of the RF generator may include adjusting set points for a process recipe performed with the process chamber. For example, set points might include a 10% power level, a 20% power level, and/or a 30% power level, etc. that is obtained by controlling/setting the amount of reflected power back to the RF generator. The calibration ensures that each set point has the proper amount of reflected power to optimize the processes of the chamber (desired thickness of deposition, etc.). Calibration adjustments also ensures that the power in the chamber is the desired power by compensating for the effects of the impedance of the MFA.

The RF generator can be calibrated and checked at each of the set points to ensure that the required amount of power is received by the chamber to ensure proper deposition and/or etching of the substrates processed in the chamber. The calibration may be performed during every preventative maintenance action due to the ease of use and short chamber down time provided by the counter-impedance matching network of the present techniques. The calibration process may also detect a damaged MFA as carbon buildup/heat damage and other issues may cause power delivery to be out of specification, indicating possible problems with the MFA integrity. One major advantage of the counter-impedance matching network of the present techniques is the ability to perform the calibration without removal of the lid cover and/or the RPS when present. No skilled personnel is required to reinstall the RPS, as the RPS does not need to be removed, saving substantial amounts of time and substantial cost savings. Frequent checking and calibration of the RF generator afforded by the counter-impedance matching network of the present techniques increases the life and optimizes the performance of the process chamber.

Embodiments in accordance with the present principles may be implemented in hardware, firmware, software, or any combination thereof. Embodiments may also be implemented as instructions stored using one or more computer readable media, which may be read and executed by one or more processors. A computer readable medium may include any mechanism for storing or transmitting information in a form readable by a machine (e.g., a computing platform or a “virtual machine” running on one or more computing platforms). For example, a computer readable medium may include any suitable form of volatile or non-volatile memory. In some embodiments, the computer readable media may include a non-transitory computer readable medium.

While the foregoing is directed to embodiments of the present principles, other and further embodiments of the principles may be devised without departing from the basic scope thereof.

1. A method of calibrating an RF generator for a process chamber, comprising:
exposing a lid connection point of a vertical electrode electrically connected to a multi-frequency adapter (MFA) by opening a lid of the process chamber to an opening angle of approximately 90 degrees or more exposing a process volume, wherein the MFA is electrically connected to the RF generator; and
positioning a counter-impedance matching network directly across a top of the process volume of the process chamber and electrically connecting a vertical input on a bottom on a first end of the counter-impedance matching network to the lid connection point of the vertical electrode, wherein the counter-impedance matching network has a first impedance with a reactive component equal and opposite to a reactive component of a second impedance of the MFA and wherein the counter-impedance matching network is connectable to a dummy load for performing a calibration of the RF generator.

2. The method of claim 1, wherein the RF generator is mounted below the process volume of the process chamber.

3. The method of claim 1, wherein the dummy load is a 50-ohm load.

4. The method of claim 1, wherein the RF generator is a high frequency RF generator.

5. The method of claim 1, wherein positioning the counter-impedance matching network directly across the top of the process volume of the process chamber includes inserting a downward protrusion positioned on a second end of the counter-impedance matching network distal to the first end of the counter-impedance matching network into an opening positioned at a front of the process chamber.

6. The method of claim 1, wherein the MFA is configured to accept a high frequency input from the RF generator and a low frequency input from another RF generator.

7. The method of claim 1, wherein the process chamber is a chemical vapor deposition (CVD) chamber.

8. The method of claim 1, wherein the process chamber has a remote plasma source (RPS) mounted to the lid which remains in-situ while the RF generator is calibrated.

9. The method of claim 1, wherein performing a calibration of the RF generator includes accounting for impedance effects of the MFA on power transmitted into the process chamber by the RF generator.

10. The method of claim 1, wherein performing a calibration of the RF generator includes adjusting set points for a process recipe performed with the process chamber.

11. The method of claim 1, wherein the counter-impedance matching network has a horizontal protrusion that allows the first end of the counter-impedance matching network to be positioned under the lid when opened to connect the vertical input to the lid connection point of the vertical electrode.

12. The method of claim 1, wherein performing a calibration of the RF generator is performed during preventive maintenance.

13. The method of claim 1, wherein performing a calibration of the RF generator is used to detect damage to the MFA.

14. The method of claim 1, wherein performing a calibration of the RF generator is performed without removing a lid cover of the process chamber.

15. A method of calibrating an RF generator for a process chamber, comprising:
exposing a lid connection point of a vertical electrode electrically connected to a multi-frequency adapter (MFA) by opening a lid of a chemical vapor deposition (CVD) process chamber to an opening angle of approximately 90 degrees or more exposing a process volume, wherein the MFA is electrically connected to the RF generator, wherein the RF generator is mounted below the process volume of the CVD process chamber, and wherein the RF generator is a high frequency RF generator; and
positioning a counter-impedance matching network directly across a top of the process volume of the CVD process chamber and electrically connecting a vertical input on a bottom on a first end of the counter-impedance matching network to the lid connection point of the vertical electrode and inserting a downward protrusion positioned on a second end of the counter-impedance matching network distal to the first end of the counter-impedance matching network into an opening positioned at a front of the CVD process chamber, wherein the counter-impedance matching network has a first impedance with a reactive component equal and opposite to a reactive component of a second impedance, wherein the counter-impedance matching network is connectable to a 50-ohm dummy load for performing a calibration of the RF generator, and wherein the calibration is performed without removing a lid cover of the CVD process chamber or a remote plasma source (RPS) of the CVD process chamber.

16. The method of claim 15, wherein the MFA is configured to accept a high frequency input from the RF generator and a low frequency input from another RF generator.

17. The method of claim 15, wherein performing a calibration of the RF generator includes accounting for impedance effects of the MFA on power transmitted into the process chamber by the RF generator.

18. The method of claim 15, wherein performing a calibration of the RF generator includes adjusting set points for a process recipe performed with the process chamber.

19. The method of claim 15, wherein performing a calibration of the RF generator is used to detect damage to the MFA.

20. An apparatus for calibrating an RF generator of a process chamber, comprising:
a counter-impedance matching network that is configured to be positionable directly across a top of a process volume of the process chamber when a lid of the process volume is opened to an angle of approximately 90 degrees or more exposing the process volume,
wherein the counter-impedance matching network has a vertical input on a bottom of a first end of the counter-impedance matching network that is configured to connect with a lid connection point of a vertical electrode electrically connected to a multi-frequency adapter (MFA),
wherein the counter-impedance matching network has a second end distal to the first end with a downward protrusion that is configured to be insertable into an opening positioned at a front of the process chamber, and
wherein the counter-impedance matching network has a first impedance with a reactive component equal and opposite to a reactive component of a second impedance of the MFA.
